(19) United States
(12) Patent Application Publication
(10) Pub. No.: US 2024/0218228 A1
(43) Pub. Date: Jul. 4, 2024

(54) LOW MELT POINT METAL BASED THERMAL INTERFACE MATERIAL

(71) Applicant: Honeywell International Inc., Charlotte, NC (US)

(72) Inventors: Yaqun Liu, Hangzhou (CN); Yunyun Zhang, Zhangjiagang (CN)

(21) Appl. No.: 18/523,255

(22) Filed: Nov. 29, 2023

Related U.S. Application Data
(60) Provisional application No. 63/433,608, filed on Dec. 19, 2022.

(51) Int. Cl. C09K 5/06; H01L 23/00; H01L 23/367

(52) U.S. Cl. CPC C09K 5/06; H01L 23/367; H01L 24/27; H01L 24/29; H01L 24/32; H01L 2224/2732; H01L 2224/29105; H01L 2224/32221; H01L 2924/049; H01L 2924/0715

(57) ABSTRACT

A thermal interface material including at least a low melting point gallium alloy and a mercapto group-containing silicone oil, as well as an emulsifying compound, at least one polymer, a thermally conductive powder, and a coupling compound.

### CROSS-REFERENCE TO RELATED APPLICATION

This application claims priority to U.S. Provisional Patent Application No. 63/433,608, filed Dec. 19, 2022, which is herein incorporated by reference in its entirety.

### FIELD

The present disclosure generally relates to thermal interface materials, and more particularly, to thermal interface materials that include a low melting point metal alloy.

### BACKGROUND

Thermal interface materials (TIMs) are widely used to dissipate heat from electronic components, such as central processing units, video graphics arrays, servers, game consoles, smart phones, LED boards, and the like. Thermal interface materials are typically used to transfer excess heat from the electronic component to a heat spreader, such as a heat sink.

A practice in the industry becoming more common is to use TIMs that include, among other materials, thermal greases, phase change materials (PCM) and/or gap fillers. Compared to conventional TIMs (e.g., thermal greases, PCMs, gap fillers) liquid metal (LM)-based TIMs offer several advantages owing to their intrinsically high thermal conductivities, non-toxic, and low melting points, and effectively reduced the thermal resistance between chips and heat dissipation units. However, traditional LM-based TIMs may react with metal substrates and damage the metal surface; may be hard to compress; have high surface tension and poor wettability; and/or be flowable such that it is easy to short-current the circuit for leakage. As such, there is a need for LM-based TIM compositions that do not exhibit such drawbacks.

### SUMMARY

The present disclosure provides compositions for a thermal interface material, comprising a low melting point gallium alloy; and a mercapto group-containing silicone oil.

The present disclosure also provides a method for applying a thermal interface material to a substrate, the method comprising combining each of a low melting point gallium alloy, a mercapto-group containing silicone oil, an emulsifying compound, at least one polymer, a thermally conductive powder, and a coupling compound to form the thermal interface material; and applying the thermal interface material to a metal substrate.

The present disclosure also provides compositions for an electronic component comprising a heat sink; an electronic chip; and a thermal interface material positioned between the heat sink and the electronic chip, wherein the thermal interface material comprises: a low melting point gallium alloy; and a mercapto group-containing silicone oil.

### BRIEF DESCRIPTION OF THE DRAWINGS

The above-mentioned and other features and advantages of this disclosure, and the manner of attaining them, will become more apparent and the invention itself will be better understood by reference to the following description of embodiments of the invention taken in conjunction with the accompanying drawings, wherein:

FIG. 1A schematically illustrates an electronic chip, a heat spreader, a heat sink, and first and second thermal interface materials;

FIG. 1B schematically illustrates an exemplary thermal interface material positioned between an electronic chip and a heat sink;

FIG. 1C schematically illustrates an exemplary thermal interface material positioned between a heat spreader and a heat sink; and

FIG. 1D schematically illustrates an exemplary thermal interface material positioned between an electronic chip and a heat spreader.

Corresponding reference characters indicate corresponding parts throughout the several views. The exemplifications set out herein illustrate exemplary embodiments of the invention and such exemplifications are not to be construed as limiting the scope of the invention in any manner.

### DETAILED DESCRIPTION

The present invention relates to thermal interface materials useful in transferring heat away from electronic components. Specifically, the present invention relates to liquid metal thermal interface materials, which include a relatively high weight percent of a low melting point metal alloy, useful in transferring heat away from electronic components.

### I. Thermal Interface Material Composition:

The present invention relates to thermal interface materials (TIMs) useful in transferring heat away from electronic components, which resolve the issues associated with traditional liquid Metal TIMs. The thermal interface material composition may include one or more of a low melting point (e.g., liquid, softened, etc.) metal alloy, a functional silicone oil (e.g., a mercapto/thiol functionalized silicon oil), a thermal conductive filler, a coupling agent/compound, and a surfactant/emulsifying agent. In some exemplary embodiments, the TIM is prepared by combining the individual components in a heated mixer and blending the composition together. The blended composition may then be applied directly to the substrate, such as in a stencil-printing process.

### A. Low Melting Point Metal Alloy:

The thermal interface material composition may include a metal alloy, which can have a relatively low melting point temperature, such as less than 200° C.

In one exemplary low melting point metal alloy, the metal alloy may comprise gallium, bismuth, tin, indium or any combination thereof.

In another exemplary low melting point metal alloy, the metal alloy may comprise gallium or the gallium alloys in which may be combination with other metal elements.

In one exemplary low melting point metal alloy, the metal alloy may comprise bismuth alloys which may be combined with other metal elements.

Some low melting point metal alloys, such as those with the a melting point of 0-25° C. may include GaInSnZn alloy, GaInSn alloy, GaInZn alloy, GaIn alloy; those with a melting point of 25-60° C. may include Ga, BiPbInSnCd alloy, BiInSn alloy, InBiCd alloy; those with a melting point of 60-120° C. may include GaInBi alloy, BiInSn alloy, InBiCd alloy, BiPbInSnCd alloy, BiPbSnCd alloy, BiPbInSn alloy, InBi alloy, BiPbSn alloy, InSn alloy, BiPbIn alloy, BiPbSnAg alloy; and those with a melting point of 120-200° C. may include BiSnZn alloy, BiSn alloy, BiPb alloy, InSnPb alloy, BiPbSn alloy, InAg alloy, InPbAg alloy, InBi alloy, SnPbIn alloy, SnPbBi alloy, SnPbBi alloy, SnBi alloy, InPb alloy, SnPbAg alloy, SnPb alloy, SnZn alloy, SnPbSb alloy, PbIn alloy, SnAg alloy.

For example, the metal alloy may have a melting point temperature that is at, near, or below room/ambient temperatures (e.g., between 50° F.-85° F., and preferably below 60° F.). This relatively low melting point makes the metal alloy a liquid, or at least a softened solid, at ambient temperatures. In this case, the metal alloy may be based upon one of, or a combination of, a variety of metallic alloy materials which are liquids at or near room temperature, such as gallium. For example, the low melting point metal alloy may be an alloy comprising gallium (Ga), indium (In), and/or tin (Sn), such as Ga_{62.5}In_{21.5}Sn₁₆, Ga₇₅In₂₅, Ga_{68.5}In_{21.5}Sn₁₀. The inclusion of the low melting point metal alloy within the TIM results in a “liquid metal” (e.g., a metal alloy that may be flowable, or at least softened, at ambient conditions) thermal interface material (LM TIM) that exhibits enhanced thermal conductivity and heat dissipation.

Traditionally, liquid metals used in TIMs are reactive with metal substrates, difficult to compress, have high surface tension and bad wettability, and are flowable such that the electrical component may short-current if there is current leakage. To avoid the foregoing characteristics of traditional liquid metal TIMs, liquid metals may be combined with one or more other compounds, such as with functionalized silicon oils, as will be described in more detail herein, where the liquid metal has a coupling effect with one or more of the components of the thermal interface material (e.g., the thiol functional silicone oil, as described herein) such that the foregoing characteristics are lessened.

The thermal interface material provided by the present disclosure can comprise a relatively high weight percent of the low melting point metal alloy (e.g., the gallium-based alloy) such as anywhere from 80 wt. %, 85 wt. %, 88 wt. %, 89 wt. %, 90 wt. %, 91 wt. %, 92 wt. %, 93 wt. %, 94 wt. %, 95 wt. %, 96 wt. %, and/or 97 wt. %, or within any range using any two of the foregoing as endpoints, where wt. % is based on the total weight of the thermal interface material. For example, the low melting point metal alloy may comprise from 80 wt. % to 97 wt. %, from 85 wt. % to 96 wt. %, from 89 wt. % to 95 wt. %, 90 wt. % to 94 wt. %, and/or 91 wt. % to 93 wt. % of the total weight of the thermal interface material.

### B. Functionalized Silicone Oil

The thermal interface material composition can include a functionalized silicone oil. In this case, the silicon oil may be functionalized with any one of, or a combination of, a thiol/mercapto functional group, a halogen functional group (e.g., chlorine, fluorine, etc.), a hydroxyl group (e.g., an alcohol), and/or a amine functional group. The functionalization of the silicon oil decreases the surface tension and improves the wettability and compressibility of the overall low melting point metal alloy-based TIM formulation. Traditionally, the use of non-functionalized silicone oils within low melting point based TIMs result in non-stability during printing. In this case, the silicon oil may be functionalized with a mercapto/thiol functional group, resulting in a mercapto functional silicon oil, which, when combined with the low melting point meal alloy, avoids the non-stability issues during printing since a mercapto functional silicone oil generates a coupling effect with the low melting point metal alloy.

In some exemplary functional silicone oil composition, the silicone oil may containing at least one mercapto group. The thiol function may include mercapto alkyl terminated poly(alkyl)(alkyl)siloxane, mercapto alkyl terminated poly(alkyl)(alkoxyl)siloxane, poly(mercaptoalkyl)alkylsiloxane, poly(mercaptoalkyl)(alkoxyl)siloxane or the copolymer thereof.

In some exemplary thiol/mercapto functional silicone oil compositions, the mercapto alkyl terminated poly(alkyl)(alkyl)siloxane may include (HS)ₙ₁—R1-Si(CH₃)₂—[O—Si(CH₃)₂]ₙ₃—R2-(SH)ₙ₂, (HS)ₙ₁—R1-Si(CH₃)(C₄H₉)—[O—Si(CH₃)(C₄H₉)]ₙ₃—R2-(SH)ₙ₂, (HS)ₙ₁—R1-Si(CH₃)₂—[O—Si(CH₃)₂]ₙ₃—[O—Si(CH₃)(C₄H₉)]ₙ₄—R2-(SH)ₙ₂, (HS)ₙ₁—R1-Si(CH₃)₂—[O—Si(CH₃)₂]ₙ₃—[O—Si(CH₃)(C₂H₅)]ₙ₄—[O—Si(CH₃)(C₈H₁₇)]ₙ₅—R2-(SH)ₙ₂, wherein n1, n2, n3, n4, n5 are integers with n1+n2≥1, and R1 and R2 are organic groups.

In some exemplary thiol/mercapto functional silicone oil composition, the mercapto alkyl terminated poly(alkyl)(alkoxyl)siloxane may include (HS)ₙ₁—R1-Si(CH₃)(OCH₃)—[O—Si(CH₃)(OCH₃)]ₙ₃—R2-(SH)ₙ₂, (HS)ₙ₁—R1-Si(CH₃)(C₄H₉)—[O—Si(CH₃)(OCH₃)]ₙ₃—[O—Si(CH₃)₂]ₙ₄—R2-(SH)ₙ₂, (HS)ₙ₁—R1-Si(CH₃)₂)—[O—Si(CH₃)(OCH₃)]ₙ₃—[O—Si(CH₃)₂]ₙ₄—[O—Si(CH₃)(C₄H₉)]ₙ₅—R2-(SH)ₙ₂, wherein n1, n2, n3, n4, n5 are integers with n1+n2≥1, and R1 and R2 are organic groups.

In some exemplary thiol/mercapto functional silicone oil compositions, the poly(mercaptoalkyl)alkylsiloxane may comprise the group —{O—Si—(R1)[—R2-(SH)ₙ₁]}ₙ₂—, wherein n1, n2 are integers not less than 1, and R1 and R2 are organic groups.

In some exemplary thiol/mercapto functional silicone oil compositions, the poly(mercaptoalkyl)(alkoxyl)siloxane may comprise the group —{O—Si—(O—R1)[—R2-(SH)ₙ₁]}ₙ₂—, wherein n1, n2 are integers not less than 1, and R1 and R2 are organic groups.

In some exemplary thiol/mercapto functional silicone oil composition, the silicone oil may be as

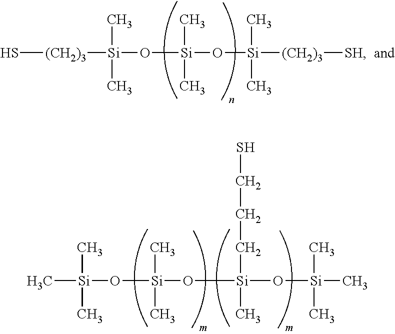

In one exemplary thiol/mercapto functional silicone oil composition, the average molecule weight(Mw) of the composition may be not less than 200, preferred not less than 500, more preferred not less than 1000, much more preferred not less than 2000.

In one exemplary thiol/mercapto functional silicone oil composition, the average molecule weight(Mw) of the composition may from as low as 200, 300, 500, 800, 1000, 2000 to as high as 3000, 5000, 10000, 20000, 50000, 100000, 500000, 1000000, 5000000.

The thermal interface material composition provided by the present disclosure can comprise a weight percentage of a functionalized silicone oil (e.g., a thiol/mercapto functionalized silicon oil) from, for example, 0.1 wt. %, 0.4 wt. %, 0.8 wt. %, 1.2 wt. %, 1.6 wt. %, 2 wt. %, 2.4 wt. %, 2.8 wt. %, 3 wt. %, 5 wt. %, and/or 7 wt. %, or within any range using any two of the foregoing as endpoints, where wt. % is based on the total weight of the thermal interface material composition. For example, the thermal interface material may comprise from 0.1 wt. % to 7 wt. %, from 0.1 wt. % to 5 wt. %, and/or from 0.1 wt. % to 3 wt. % of the total weight of the thermal interface material composition.

In one exemplary functional silicone oil, the thiol/mercapto functional silicone oil composition was prepared by thiol-ene chemical reaction process. For example, the synthesis of chain thiol silicone oil is achieved by the reaction of polythiol (polymeric mercapto group-containing thiol) and carbon-carbon unsaturated bond functioned silicone oil with molar ratio 0.1:1 to 1:0.1, preferred 2:1, 1:1 or 1:2.

In one exemplary thiol functionalization reaction, the polythiol is an organic molecule containing at least two mercapto groups and having the general formula R—(SH)ₙ, Wherein R is an organic moiety having a valence n, and n is at least 2, for example, 1, 2-ethanedithiol, 1, 3-propanedithiol, 1, 8-octanedithiol, 2, 3-butanedithiol, 1, 9-nonanedithiol, 2,2′-(1, 2-ethanediylberoxy) bisethanethiol, pentaerythritol tetrakis (3-mercaptopropionate), mercaptosilicone oils, pentaerythritol tetrakis (3-mercaptobutyrate), and so on. The thiol functional silicone oil composition provided by the present disclosure can comprise a weight percent of the polymeric mercapto group-containing thiol, for example, from 15 wt. %, 20 wt. %, 25 wt. %, 30 wt. %, 35 wt. %, 40 wt. %, 45 wt. %, 50 wt. %, 55 wt. %, or 60 wt. %, or within any range using any two of the foregoing as endpoints, where the wt. % is based on the total weight of the thiol functional silicone oil. For example, the polymeric mercapto group-containing thiol may comprise from 15 wt. % to 60 wt. %, from 20 wt. % to 55 wt. % and/or from 25 wt. % to 50 wt. % of the total weight of the thiol functional silicone oil.

In one exemplary thiol functionalization reaction, the ene (carbon-carbon unsaturated bond) composition may comprise the silicone oil with —C(R1)═C(R2)— group, wherein R1 and R2 are H or organic groups independently.

In one exemplary thiol functionalization reaction, the ene (carbon-carbon unsaturated bond) composition may comprise the silicone oil with vinyl group, acetylene group, acrylic group, methacrylic group, or the combination thereof.

In one exemplary ene (carbon-carbon unsaturated bond) composition, the vinyl group, acetylene group, or acrylic group is/are single terminated, double terminated or grafted on the silicone oil.

In one exemplary ene (carbon-carbon unsaturated bond) composition, the average molecule weight(Mw) of silicone oil with —C(R1)═C(R2)— group may be not less than 100, preferred not less than 500, more preferred not less than 1000, much more preferred not less than 2000.

In one exemplary ene (carbon-carbon unsaturated bond) composition, the average molecule weight(Mw) of silicone oil with —C(R1)═C(R2)— group may from as low as 200, 300, 500, 800, 1000, 2000 to as high as 3000, 5000, 10000, 20000, 50000, 100000, 500000, 1000000, 5000000.

In the case of thiol functionalization, the thiol functional silicone oil may be created by mixing a polymeric mercapto group-containing thiol, an acrylic-containing silicone oil, and a photoinitiator. The thiol functional silicone oil may be prepared by the following reaction mechanism:

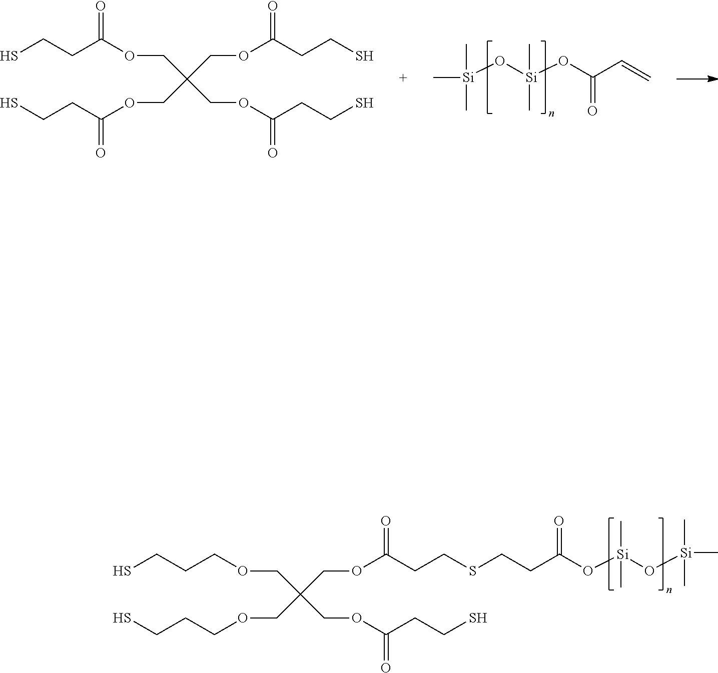

In one exemplary thiol functional silicone oil composition, pentaerythritol tetra(3-mercaptopropionate) is mixed with a methacrylic or acrylic containing chemicals. In one exemplary thiol functional silicone oil composition, pentaerythritol tetra(3-mercaptopropionate) is mixed with a polysiloxane containing methacrylic or acrylic group(s) on single terminal or multi-terminals functional modified silicone oil at a 1:1 mol ratio, and the photoinitiator is further added with 0.5% wt. of the solution. The components of the composition are mixed and exposed to UV light for 30 min to result in the thiol functional silicone oil.

Exemplary acrylic-containing silicone oils may be selected from any number of long-chain silicon oils that includes one or multi acrylic functional groups (e.g., methacrylic functionalized silicon oils) including: (A1)ₙ₁—R1-Si(R11)(R12)—[O—Si(R13)(R14)]ₙ₃—R2-(A2)ₙ₂, wherein n1, n2, n3 are integers with n1+n2≥1; R1 and R2 are organic groups independently; R11, R12, R13 and R14 are organic groups(alkyl groups or alkoxyl groups, for example) independently; A1 and A2 are acrylic group or methacrylic group independently.

In one exemplary ene (carbon-carbon unsaturated bond) composition, vinyl-containing silicone oils may be selected from any number of long-chain silicon oils that includes one or multi acrylic functional groups comprise (CH₂═CH)ₙ₁—R1-Si(R11)(R12)—[O—Si(R13)(R14)]ₙ₃—R2—(CH═CH₂)ₙ₂, wherein n1, n2, n3 are integers with n1+n2≥1; R1 and R2 are organic groups independently; R11, R12, R13 and R14 are organic groups(alkyl groups or alkoxyl groups, for example) independently.

Exemplary ene (carbon-carbon unsaturated bond) composition includes monovinyl based silicone-oil, such as

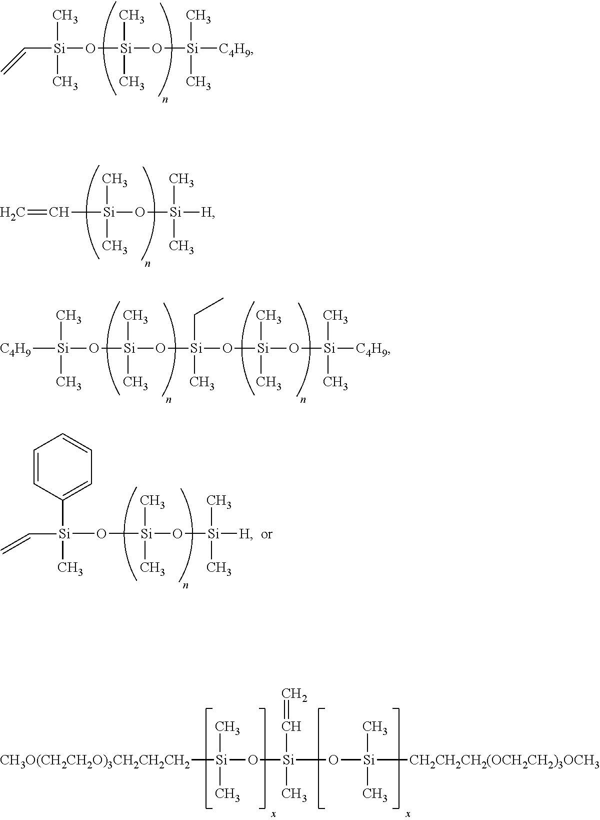

Exemplary ene (carbon-carbon unsaturated bond) composition includes monoacryl based silicone-oil, such as

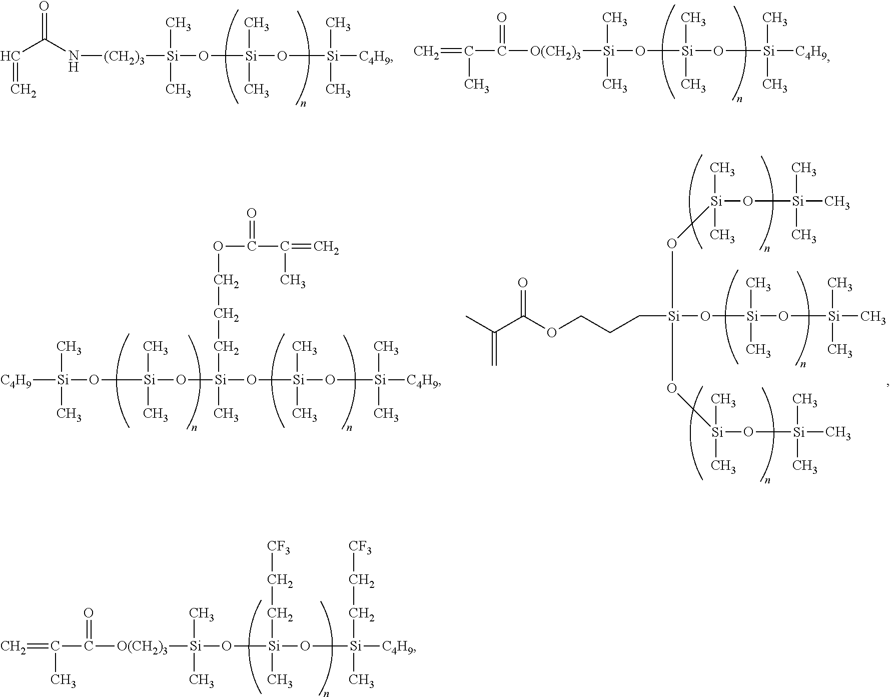

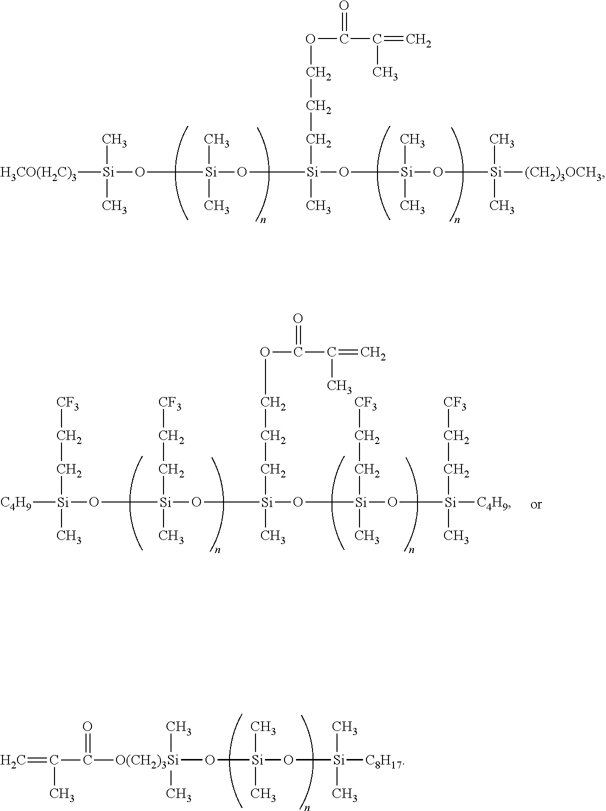

Exemplary ene (carbon-carbon unsaturated bond) composition includes multi carbon-carbon unsaturated groups based silicone-oil, such as

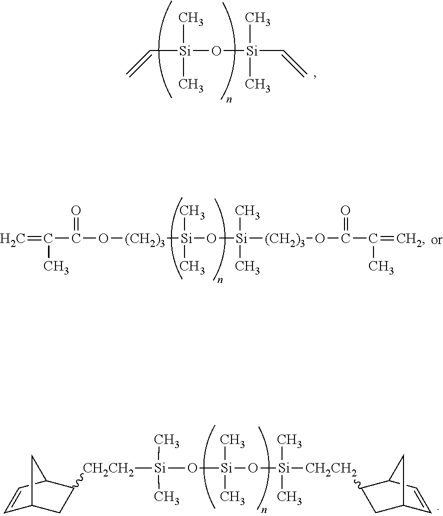

Vinyl silicone oil is polysiloxane containing only one vinyl. The vinyl can be at the end of the silica framework or on either side, for example. The thiol functional silicone oil composition provided by the present disclosure can comprise a weight percent of acrylic-containing silicone oil, for example, from 15 wt. %, 20 wt. %, 25 wt. %, 30 wt. %, 35 wt. %, 40 wt. %, 45 wt. %, 50 wt. %, 55 wt. % and/or 60 wt. %, or within any range using any two of the foregoing as endpoints, where the wt. % is based on the total weight of the thiol functional silicone oil. For example, the acrylic-containing silicone oil may comprise from 15 wt. % to 60 wt. %, from 20 wt. % to 55 wt. % and/or from 25 wt. % to 50 wt. % of the total weight of the thiol functional silicone oil.

In the case of thiol functionalization reaction, one initiator may be further involved. The initiator may comprise, or example, a photoinitiator or a heat-sensitive initiator, or the mixtures thereof. An exemplary photoinitiator may include radical photoinitiators, commercially available in large number from companies such as Ciba Specialties (trade names Irgacure and Darocure), Lamberti (Esacure), BASF (Lucirin), Sartomer (Lambson) and many others. The radical photointiators are widely used in UV-curing adhesive, coating or inks. The common examples of photoinitiators include, but not limited to Benzoin methyl ether, Benzophenone(BP), bis(4,4′-dimethylamino)benzophenone, Thioxanthones(such as the 2-isopropyl derivative, ITX), 9,10-Anthraquinone, Camphorquinone, 3-Ketocoumarins, 2,2-Dimethoxy-2-phenylacetophenone, 2-Hydroxy-2-methylphenylpropane-1-one (photoinitiator 1173), alpha-Hydroxy-acetophenone, Bis(2,6-dimethoxybenzoyl)-2,4,4-trimethylpentylphosphine oxide, 2,4,6-Trimethylbenzoyldiphenylphosphine oxide, Bis(2,6-dichlorobenzoyl)-(4-propylphenyl)-phosphine oxide, and mixtures thereof. The heat-sensitive radical initiator includes, but is not limited to, Azobisisobutyronitrile, Azobisisoheptonitrile, Azobiscyanovaleric acid, Dimethyl azobisisobutyrate, 2′-Azobis (4-methoxy-2, 4-dimethylvaleronitrile), Benzoyl peroxide, Potassium persulfate or Ammonium persulfate. The thiol functional silicone oil composition provided by the present disclosure can comprise a weight percent of the photoinitiator, for example, from 0.1 wt. %, 0.3 wt. %, 0.5 wt. %, 0.7 wt. %, 0.9 wt. %, 1 wt. %, or 2 wt. %, or within any range using any two of the foregoing as endpoints, where the wt. % is based on the total weight of the thiol functional silicone oil. For example, the photoinitiator may comprise from 0.1 wt. % to 2 wt. %, 0.1 wt. % to 1.5 wt. % and/or 0.1 wt. % to 1 wt. % of the total weight of the thiol functional silicone oil.

### C. Thermally Conductive Filler

The thermal interface material composition may include one or more thermally conductive fillers. The thermally conductive filler may increase the thermal conductivity of the thermal interface material while decreasing any sedimentation when forming the LM TIM composition.

Exemplary thermally conductive fillers can include any one of, or combination of, metals, alloys, nonmetals, metal oxides, and/or ceramics. The metals can include, but are not limited to, aluminum, copper, silver, zinc, nickel, tin, indium, and lead. The nonmetal can include, but are not limited to, carbon, graphite, carbon nanotubes, carbon fibers, graphenes, boron nitride, and silicon nitride. The metal oxide or ceramics can include, but not limited to, alumina (aluminum oxide), aluminum nitride, boron nitride, zinc oxide, and tin oxide. In one exemplary embodiment, the filler is Aluminum nitride.

The thermal interface material composition provided by the present disclosure can comprise a weight percent of one or more thermally conductive fillers of, for example, from 0 wt. %, 0.1 wt. %, 1 wt. %, 5 wt. %, 8 wt. %, or 10 wt. %, or within any range using any two of the foregoing as endpoints, where wt. % is based on the total weight of the TIM composition. For example, the thermally conductive filler may comprise from 0 wt. % to 10 wt. %, from 0.1 wt. to 8 wt. %, and/or from 1 wt. % to 5 wt. %.

The thermally conductive filler(s) may be selected based upon average particle size. For instance, a smaller particle size may be selected based upon a desired higher fill density and result in a higher coating performance for the LM TIM composition. In this case, the thermally conductive filler can have an average particle size of as little as 0.1 microns, 1 micron, 10 microns, as great as 50 microns, 75 microns, or 100 microns or within any range defined between any two of the foregoing values.

### D. Coupling Agent

The thermal interface material composition provided by the present disclosure may comprise one or more coupling agents. Exemplary coupling agents include silane coupling agents with general formula Y—(CH2)n—Si—X3, wherein Y is organofunctional group, X is hydrolysable group. Organofunctional group Y includes alkyl, glycidoxy, acryloxyl, methylacryloxyl, amine, or a combination thereof. Hydrolysable group X includes alkyloxy, acetoxy. In some exemplary embodiments, the silane coupling agent includes alkyltrialkoxysilanes. Exemplary alkytrialkoxy silane comprise decyltrimethoxylsilane, undecyltrimethoxylsilane, hexadecyltrimethoxysilane, octadecyltrimethoxysilane, or dodecyltrimethyloxysilane. In one exemplary embodiment, the LM TIM includes dodecyltrimethyloxysilane as the coupling agent as shown in the formula below.

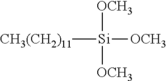

The coupling agent may increase the dispersion and wettability of the LM TIM composition.

The thermal interface material composition provided by the present disclosure can comprise a weight percent of one or more coupling agents of, for example, from 0 wt. %, 0.2 wt. %, 0.23 wt. %, 0.25 wt. %, 0.27 wt. %, 0.3 wt. %, or 0.33 wt. %, 0.35 wt. %, 0.37 wt. %, 0.4 wt. %, 0.45 wt. %, or 0.5 wt. % or within any range using any two of the foregoing as endpoints, where wt. % is based on the total weight of the TIM composition. For example, the one or more coupling agents may comprise from 0 wt. % to 0.5 wt. %, from 0.2 wt. % to 0.45 wt. %, from 0.23 wt. % to 0.4 wt. %, from 0.25 wt. % to 0.37 wt. %, from 0.27 wt. % to 0.35 wt. %, or from 0.3 wt. % to 0.33 wt. % of the total weight of the TIM composition.

### E. Emulsion Agent/Surfactant

The thermal interface material composition provided by the present disclosure may comprise one or more surfactants which may act as an emulsifying agent. The emulsion agent/surfactant may include cationic surfactant, anionic surfactant, nonionic surfactant or the mixture thereof.

Exemplary surfactants may include nonionic surfactants includes glycerin esters (e.g. mono-glyceride, diglyceride), polyethylene glycol ester, sorbitan esters (e.g. sorbitan trioleate, sorbitan monooleate), polyoxyethylene sorbitan esters (e.g. polyoxyethylene sorbitan trioleate, polyoxyethylene sorbitan monooleate), polysorbates (e.g. polysorbate 40, polysorbate 80), or the mixture thereof.

Exemplary surfactants may include Span-85, Span-80, Span-60, Span C12 and 1ATC9, tween-85, tween-60, dopamine, dopamine hydrochloride, 3-mercapto N-propionamide, and polyvinylpyrrolidone, 1-dodecanethiol, cetrimonium bromide, poly(4-vinyl1-methyl-pyridinium bromide), lysozyme, and trithiocarbonatefunctionalized brushed polyethylene glycol, 3-chloropropyltriethoxysilane, 3-Aminopropyltriethoxysilane, 3-Mercaptopropyltriethoxysilane, and the mixtures thereof. Surfactants and emulsion agents may improve the stability of the liquid metal between the dispersed alloy phase and the organic phase.

Thermal interface material provided by the present disclosure can comprise a weight percent of one or more surfactants or emulsifying agents, for example, from 0 wt. %, 0.1 wt. %, 0.3 wt. %, 0.5%, 0.6 wt. %, 0.7 wt. %, 0.8 wt. %, 0.9 wt. %, 1 wt. %, 1.1 wt. %, 1.2 wt. %, 1.3 wt. %, 1.4 wt. %, 1.5 wt. %, 2 wt. % and/or 3 wt. % or within any range using any two of the foregoing as endpoints, where wt. % is based on the total weight of the thermal interface material composition. For example, the surfactant can comprise from 0 wt. % to 3 wt. %, from 0.1 wt. % to 2 wt. %, from 0.3 wt. % to 1.5 wt. %, from 0.5 wt. % to 1.4 wt. %, from 0.6 wt. % to 1.3 wt. %, from 0.7 wt. % to 1.2 wt. %, from 0.8 wt. % to 1.1 wt. % and/or from 0.9 wt. % to 1 wt. % of the total weight of the thermal interface material

### II. Properties of the Low Melting Point Ga-Based Thermal Interface Material:

The thermal interface material of the present disclosure may exhibits relatively high thermal conductivity. For example, a gallium-based thermal interface material provided by provided by the present disclosure can comprise a thermal conductivity, for example, from 2 W/(m·k), 3 W/(m·k), 4 W/(m·k), 5 W/(m·k), 6 W/(m·k), 7 W/(m·k), 8 W/(m·k), 9 W/(m·k), 10 W/(m·k), 11 W/(m·k), or 12 W/(m·k), or within any range using any two of the foregoing as endpoints, as determined per ASTM D5470. For example, the thermal conductivity may comprise between 2 W/(m·k) and 12 W/(m·k), 3 W/(m·k) and 11 W/(m·k), and 4 W/(m·k) and 10 W/(m·k). In one exemplary embodiment, the thermal interface material exhibits a thermal conductivity of 8 W/(m·k), as determined per ASTM D5470.

Thermal impedance (TI) testing characterizes the ability of a composition to diffuse heat from one electrical component to the remainder of the electrical device. Gallium-based thermal interface materials provided by the present disclosure can comprise a TI, for example, within a range from 0.01 or 0.06 C ° C.·cm2/W as determined per ASTM D5470. In one exemplary embodiment, the thermal interface material exhibits a thermal impedance of 0.01 to 0.05 C ° C.·cm2/W, as measured by ASTM D5470.

### III. Applications Utilizing the Thermal Interface Material

The thermal interface material composition provided by the present disclosure may be used as the thermal interface material in a variety of electronic components contexts.

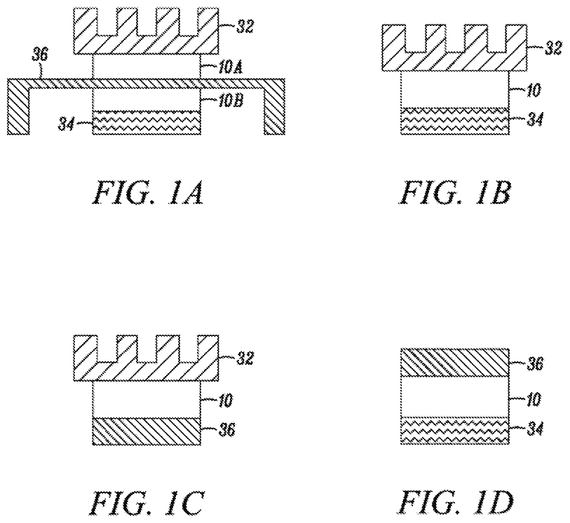

For example, FIG. 1A schematically illustrates an electronic chip 34, a heat spreader 36, and a heat sink 32 with a first thermal interface material (TIM) 10A connecting the heat sink 32 and heat spreader 36, and a second thermal interface material 10B connecting the heat spreader 36 and electronic chip 34. One or both of thermal interface materials 10A and/or 10B may be a comprise the low melting point thermal interface material composition described previously. FIG. 1B illustrates the exemplary thermal interface material 10 as a thermal interface layer designated as a TIM positioned between an electronic chip 34 and a heat sink 32, such that a first surface of TIM 10 is in contact with a surface of electronic chip 34 and a second surface of TIM 1 is in contact with a surface of heat sink 32. As with FIG. 1A, TIM 10 can comprise the low melting point thermal interface material composition described previously. FIG. 1C illustrates the exemplary thermal interface material 10 as thermal interface material positioned between a heat spreader 36 and a heat sink 32, such that a first surface of TIM 10 is in contact with a surface of heat spreader 36 and a second surface of TIM 10 is in contact with a surface of heat sink 32. As with FIGS. 1A and 1B, TIM 10 can comprise the low melting point thermal interface material composition described previously. FIG. 1D illustrates an exemplary thermal interface material 10 as a thermal interface material positioned between an electronic chip 34 and a heat spreader 36 such that a first surface of TIM 10 is in contact with a surface of electronic chip 34 and a second surface of TIM 10 is in contact with a surface of heat spreader 36. AS with FIGS. 1A, 1B and 1C, TIM 10 can comprise the low melting point thermal interface material composition described previously.

The low melting point TIM of the present disclosure may be applied to a substrate using a variety of printing processes including a stencil printing process. Using a stencil can offer higher controllability and/or efficiency of the application of the TIM to electrical components. For example, by using a stencil, the LM TIM can be applied repeatedly in the same pattern on many components. Stencils can be made in a variety of shapes, allowing the LM TIM to be applied to a variety of electrical components. The TIM may be printed onto a substrate, which may be a conductive metallic substrate, such as a copper substrate or an aluminum substrate. In some cases, the conductive substrate may be a nickel coated substrate such as a nickel coated copper substrate, or a nickel coated aluminum substrate.

For example, the components of the low melting point TIM composition as provided by the present disclosure may be combined into a paste. The paste may be printed, such as by a squeegee and stencil process, onto a coated metal substrate, such as a nickel coated copper substrate or a nickel coated aluminum substrate. The top portion of the substrate may be overlain with a stencil, where the stencil comprises both a thickness (t) and a plurality of openings arranged as a mesh. The openings may be based upon a variety of geometries, including a hexagonal geometry, whereas each opening geometry comprises a length (l) (or diameter). A distance (a) between each of the openings about the mesh may be based upon the thickness (t) of the stencil, where the distance (a) is proportional to the (t). For example, in the case where the stencil comprises a relatively large thickness (t), the distance (a) between openings may be relatively large, or conversely, when the thickness (t) is relatively small, the distance (a) between openings also may be relatively small. The distance (a) between openings may also be proportional to the length of the opening (l), such that with larger length (l) vales, the distance between opening (a) may also relatively large. Each of the at least the variable (a), (l) and (t) may be adjusted, either alone or in combination, such that a desired thickness of the low melting point TIM paste is deposited onto the coated metal substrate at a desired thickness.

For example, a pattern is cut in a steel substrate using a laser or other process that results in a clean edge on the stencil geometry. Some processes such as traditional steel stamping may be avoided as they could leave a rolled edge or sharp feature that may cause the stencil not to sit flush or cause scratches in the heatsink surface. The feature size of the stencil may be small enough that the straightness of the scraper edge avoids influencing the thickness of the paste (i.e., wide openings should be avoided). A honeycomb pattern is may be used n as it gives an even distribution and can easily be specified on a drawing using two dimensions. A scraper can be used to press the paste into the stencil features, and the use of a pattern enables the scraper to remain parallel to the heatsink at all points. The pattern remains on the surface until the module has been pressed down and temperature cycled, at which point, the paste flows to fill voids. The shape, size, and spacing of the holes along with the thickness of the stencil determine how thick the resulting paste is once the module is mounted.

For example, when the length of the pattern (e.g., in a honeycomb orientation) cut into the steel plate is 2.0 mm, and the space between the individual pattern cutouts is 0.5 mm, the thickness of the resulting past may be approximately 0.08 mm. In another example, when the length of the honeycomb pattern is 3.0 mm, and the space between the individual pattern cutouts is 0.75 mm, the thickness of the resulting past may be approximately 0.1 mm. In still further examples, when the length of the honeycomb pattern is 4.0 mm, and the space between the individual pattern cutouts is either 1 mm or 2 mm, the thickness of the resulting past may be approximately 0.12 mm and in a range from 0.15 mm to 0.2 mm, respectively.

### EXAMPLES

### Example 1

A thiol functional organopolysiloxane oil was prepared according to the formulation provided in Table 1.

TABLE 1
Thiol Functional Silicon Oil Formulation (wt. %) for Example 1
Thiol Functional Organpolysiloxane Oil Formulation

| Component | Mol ratio | Wt. % Range |
|---|---|---|
| Polymeric mercapto group- | 1 | 25-50 |
| containing thiol | | |
| Acrylic-containing silicone | 1 | 25-50 |
| oil | | |
| Photoinitiator | 0.005 | 0.1%-1% |

A thermal interface material was prepared according to the formula provided in Table 2.

TABLE 2
Ga-Based Liquid Metal TIM Formulation (wt. %) for Example 1

| Component | Wt. % Range |
|---|---|
| Gallium-based liquid metal | [80-97] |
| alloy with 62.5 wt. % of Ga | |
| Surfactant/Emulsifying Agent | [0-1.5] |
| Silicon-based Polymer | [0-3] |
| Diol- modified Polymer | [0-3] |
| Thiol Functionalized Silicon Oil | [0.1-3] |
| Thermal conductive powder | [0-10] |
| Coupling Agent | [0.2-0.45] |

Substances 1, 2, 3, 4, 5 were added according to their mass ratio, mixed with SpeedMixer at 2000 rpm for 5 minutes, and then manually scraped and stirred.

Substances 6 and 7 were added to the mixture and mixed with SpeedMixer at 2000 rpm for 2 minutes. The resulting composition was then manually scraped and stirred and mixed again with SpeedMixer at 2000 rpm for 1 minutes.

The composition was then vacuumed at 1000 rpm for 2 minutes while stirring.

The resulting composition has the liquid metal coated by polymer and aluminum nitride.

The low melting point TIM produced has a thermal conductivity of 4-10 W/(m·k) using the methods of ASTM 5470 (TIM tester) and a thermal impedance of 0.01-0.05 C ° C.·cm2/W using the method of ASTM D5470 (cur bar equipment).

### Example 2

A thiol functional organopolysiloxane oil was prepared according to the formulation provided in Table 1.

A second embodiment of a thermal interface material was prepared according to the formula provided in Table 3.

TABLE 3
Ga-Based Liquid Metal TIM Formulation (wt. %) for Example 2

| Category/Purpose | Wt. % Range |
|---|---|
| Gallium-based liquid metal | [80-97] |
| alloy with 68.5 wt. % of Ga | |
| Surfactant/Emulsifying Agent | [0.5-1.5] |
| Silicon-based Polymer | [0-3] |
| Diol Modified Polymer | [0-3] |
| Functionalized Silicon Oil | [0.1-3] |
| Thermal conductive powder | [0-10] |
| Coupling Agent | [0-0.45] |

The compositions from Table 1 and Table 3 were mixed according to the method described in paragraphs [0069]-[0071].

The resulting composition has the liquid metal coated by polymer and aluminum nitride.

The low melting point TIM produced has a thermal conductivity of 4-10 W/(m·k) using the methods of ASTM 5470 (TIM tester) and a thermal impedance of 0.01-0.05 C ° ° C. cm2/W using the method of ASTM D5470 (cur bar equipment).

### Example 3

A thiol functional organopolysiloxane oil was prepared according to the formulation provided in Table 1.

A third embodiment of a thermal interface material was prepared according to the formula provided in Table 4.

TABLE 4
Ga-Based Liquid Metal TIM Formulation (wt. %) for Example 3

| Category/Purpose | Wt. % Range |
|---|---|
| Gallium-based liquid metal | [80-97] |
| alloy with 75 wt. % Ga | |
| Surfactant/Emulsifying Agent | [0.5-1.5] |
| Silicon-based Polymer | [0.1-3] |
| Diol Modified Polymer | [0-3] |
| Functionalized Silicon Oil | [0.1-3] |
| Thermal conductive powder | [0-10] |
| Coupling Agent | [0-0.45] |

The compositions from Table 1 and Table 4 were mixed according to the method described in paragraphs [0069]-[0071].

The resulting composition has the liquid metal coated by polymer and aluminum nitride.

The low melting point TIM produced has a thermal conductivity of 8 W/(m·k) using the methods of ASTM 5470 (TIM tester) and a thermal impedance of 0.01-0.05 C ° C.·cm2/W using the method of ASTM D5470 (cur bar equipment).

### Example 4

A thiol functional organopolysiloxane oil was prepared according to the formulation provided in Table 1.

A fourth embodiment of a thermal interface material was prepared according to the formula provided in Table 5.

TABLE 5
Ga-Based Liquid Metal TIM Formulation (wt. %) for Example 4

| Category/Purpose | Wt. % Range |
|---|---|
| Gallium-based liquid metal | [80-97] |
| alloy with 62.5 wt. % Ga | |
| Surfactant/Emulsifying Agent | [0.5-1.5] |
| Silicon-based Polymer | [0-3] |
| Diol Modified Polymer | [0.1-3] |
| Functionalized Silicon Oil | [0.1-3] |
| Thermal conductive powder | [0-10] |
| Coupling Agent | [0-0.45] |

The compositions from Table 1 and Table 5 were mixed according to the method described in paragraphs [0069]-[0071].

The resulting composition has the liquid metal coated by polymer and aluminum nitride.

The low melting point TIM produced has a thermal conductivity of 4-10 W/(m·k) using the methods of ASTM 5470 (TIM tester) and a thermal impedance of 0.01-0.05 C ° C.·cm2/W using the method of ASTM D5470 (cur bar equipment).

What is claimed is:

1. A thermal interface material, comprising:
a low melting point gallium alloy; and
a mercapto group-containing silicone oil.

2. The thermal interface material of claim 1, further comprising:
an emulsifying compound;
at least one polymer;
a thermally conductive powder; and
a coupling compound.

3. The thermal interface material of claim 1, wherein the low melting point gallium alloy comprises from 80 wt. % to 97 wt. % of the total weight of the thermal interface material.

4. The thermal interface material of claim 1, wherein the mercapto-group containing silicone oil comprises from 0.1 wt. % to 3 wt. % of the total weight of the thermal interface material.

5. The thermal interface material of claim 1, wherein the mercapto-group containing silicone oil comprises:
a polymeric mercapto group-containing thiol;
an acrylic-containing silicone oil; and
a photoinitiator.

6. The thermal interface material of claim 5, wherein:
the polymeric mercapto group-containing thiol comprises from 25 wt. % to 50 wt. % of the total weight of the mercapto-group containing silicone oil,
the acrylic-containing silicone oil comprises from 25 wt. % to 50 wt. % of the total weight of the mercapto-group containing silicone oil, and
the photoinitiator comprises from 0.1 wt. % to 1 wt. % of the total weight of the mercapto-group containing silicone oil.

7. The thermal interface material of claim 2, wherein the at least one polymer comprises a first polymer and a second polymer, the first polymer comprising a silicon-based polymer polymer and the second polymer comprising a diol-modified polymer.

8. The thermal interface material of claim 7, wherein the silicone-based ploymer polymer comprises from 0 wt. % to 3 wt. % of the total weight of the thermal interface material and the diol-modified polymer comprises from 0 wt. % to 3 wt. % of the total weight of the thermal interface material.

9. The thermal interface material of claim 2, wherein the thermally conductive powder comprises a metal-nitride compound and the thermally conductive powder comprises from 0 wt. % to 10 wt. % of the total weight of the thermal interface material.

10. The thermal interface material of claim 2, wherein the coupling compound comprises a silane and the coupling compound comprises from 0 wt. % to 0.45 wt. % of the total weight of the thermal interface material.

11. The thermal interface material of claim 2, wherein the emulsifying compound comprises a trioleate and the emulsifying compound comprises between 0 wt. % to 1.5 wt. % of the total weight of the thermal interface material.

12. A method for applying a thermal interface material to a substrate, the method comprising:
combining each of a low melting point gallium alloy, a mercapto-group containing silicone oil, an emulsifying compound, at least one polymer, a thermally conductive powder, and a coupling compound to form the thermal interface material; and
applying the thermal interface material to a metal substrate.

13. The method of claim 12, wherein the mercapto-group containing silicone oil comprises a polymeric mercapto group-containing thiol, an acrylic-containing silicone oil, and a photoinitiator, and the method further comprises combining each of the polymeric mercapto group-containing thiol, the acrylic-containing silicone oil, and the photoinitiator and exposing each of the polymeric mercapto group-containing thiol, the acrylic-containing silicone oil, and the photoinitiator to ultraviolet radiation for 1 minute or less.

14. The method of claim 12, wherein the metal substrate comprises a nickel coated copper substrate or a nickel coated aluminum substrate.

15. The method of claim 12, wherein the thermal interface material is applied in a stencil printing process at a rate of 10 mm/s or less.

16. An electronic component comprising:
a heat sink;
an electronic chip; and
a thermal interface material positioned between the heat sink and the electronic chip, wherein the thermal interface material comprises:
a low melting point gallium alloy; and
a mercapto group-containing silicone oil.

17. The electronic component of claim 16, wherein the thermal interface material further comprises:
an emulsifying compound;
at least one polymer,
a thermal conductive powder; and
a coupling compound.

18. The electronic component of claim 16, wherein the thermal interface material has a thermal conductivity from 4 W/(m·k) to 16 W/(m·k), as determined per ASTM D5470.

19. The electronic component of claim 16, wherein the thermal conductivity of the thermal interface material is from 4 W/(m·k) to 10 W/(m·k), as determined per ASTM D5470.

20. The electronic component of claim 16, wherein the thermal interface material has a thermal impedance from 0.01° C.·cm2/W to 0.05° C.·cm2/W, as measured per ASTM D5470.
